(19) United States
(12) Patent Application Publication
(10) Pub. No.: US 2006/0131569 A1
(43) Pub. Date: Jun. 22, 2006

(54) Organic memory device and method of manufacturing the same

(76) Inventors: Sung Yool Choi, Daejeon-city (KR); Chan Woo Park, Daejeon-city (KR); Han Young Yu, Daejeon-city (KR); Ung Hwan Pi, Daejeon-city (KR)

Correspondence Address: LADAS & PARRY LLP, 224 SOUTH MICHIGAN AVENUE, SUITE 1600, CHICAGO, IL, 60604, US

(21) Appl. No.: 11/202,447

(22) Filed: Aug. 12, 2005

(30) Foreign Application Priority Data
Dec. 21, 2004 (KR) 10-2004-0109296

(51) Int. Cl. H01L 29/08; H01L 23/48; H01L 29/792; H01L 29/00; H01L 29/788

(52) U.S. Cl. 257/40; 257/534; 257/759; 257/324; 257/321

(57) ABSTRACT

An organic memory device and a method of manufacturing the same are disclosed. The organic memory device includes an electron channel layer including an organic layer, in which nano particles of a uniform size are dispersed, interposed between metal electrodes, thus having electrical bistability. The organic memory device uses a change of electrical conductivity which results from a substantial change of the electrical structure of the electron channel layer when a voltage is applied. The organic memory device can be integrated using a simple manufacturing process, and ensures uniformity between devices due to the threshold voltage characteristics, even when highly miniaturized.

### CROSS-REFERENCE TO RELATED PATENT APPLICATIONS

This application claims the benefit of Korean Patent Application No. 10-2004-0109296, filed on Dec. 21, 2004, in the Korean Intellectual Property Office, the disclosure of which is incorporated herein in its entirety by reference.

### BACKGROUND OF THE INVENTION

1. Field of the Invention

The present invention relates to an electronic device, and more particularly, to a highly integrated organic memory device and a method of manufacturing the same.

2. Description of the Related Art

Giga-bit DRAMs have been made possible by improvements in semiconductor memory techniques. By the year 2010, it is expected that 100 giga-bit memory devices will be developed. The development of semiconductor memory techniques aids the production of miniaturized semiconductor devices with high speed, large capacity, high integration, low power consumption, and high performance. Ultimately, in a ubiquitous communication environment, important components can be provided in the form of systems-on chip (SoC).

Currently, flash memory, based on the control of electric charge, dominates non-volatile memory techniques. By 2007, flash devices with 65 nm nodes are expected to be produced, and such flash devices require a very thin tunneling oxide.

Although a flash memory operates at a CMOS operating voltage, programming or erasing of the flash memory is performed by 17V to 20V, which is generated by charge pumping 1.5V to 5V. That is, programming or erasing requires a high voltage, which may break down a tunneling oxide layer, thereby decreasing reliability. An equivalent oxide thickness (EOT) can be considered in a flash memory device. However, the consideration of EOT may complicate the manufacturing process. Noise between cells may be increased as devices are scaled down to 65 nm or less.

In addition, it is difficult for conventional flash memory devices to have a sufficient cell current device specific margin when they operate at a low voltage, which is required for low power consumption. Therefore, a new memory device must be developed to replace conventional memory devices and overcome these physical and electrical problems. A major candidate which has drawn much attention is the organic memory device.

In theory, organic memories are more suitable for high integration than conventional memories due to their small cell areas, less than about 4F², for example. However, based on up-to-date research results, the thermal and chemical stability of polymers or organic materials cannot be guaranteed under memory operating conditions. In addition, organic materials and conventional inorganic materials must be processed using different methods. Therefore, new processing techniques suitable for the integration of organic or polymer memories are required, such as patterning suitable for the characteristics of organic materials, organic deposition techniques, organic etching techniques, and low-temperature electrode forming techniques, or the like.

### SUMMARY OF THE INVENTION

The present invention provides an organic memory device which can decrease the size of a device and increase uniformity between cells and the data retention time, and a method of manufacturing the same.

According to an aspect of the present invention, there is provided an organic memory device including: a bottom electrode; a top electrode facing the bottom electrode; and an electron channel layer, interposed between the bottom electrode and the top electrode, and comprising: a first organic layer; a layer of nano particles separated by a uniform distance and arrayed on the first organic layer; and a second organic layer covering the nano particles.

According to another aspect of the present invention, there is provided an organic memory device including: a bottom electrode; a top electrode facing the bottom electrode; and an electron channel layer, interposed between the bottom electrode and the top electrode, and including: an organic layer; and nano particles which are separated from each other and dispersed in the organic layer.

According to still another aspect of the present invention, there is provided a method of manufacturing an organic memory device, the method including: forming a bottom electrode; forming a first organic layer on the bottom layer; dispersing synthesized metal nano particles in a solvent to make a suspension solution; coating the suspension solution on the first organic layer; vaporizing the solvent from the coated solution, thus leaving the metal nano particles on the first organic layer; and forming a second organic layer on the residual metal nano particles; and forming a top electrode on the organic layer.

According to yet another aspect of the present invention, there is provided a method of manufacturing an organic memory device, the method including: forming a bottom electrode; mixing an organic material and the synthesized metal nano particles; forming an electron channel layer by coating the resulting mixture on the bottom electrode; and forming a top electrode on the organic layer.

The electron channel layer may exist in a high conductance state or in a low conductance state according to an external voltage.

The size of the nano particles may be in the range of 1 nm to 20 nm.

The nano particles may have a uniform size and may be separated from each other by a uniform distance.

The nano particles may be composed of Al, Au, Ag, Co, Ni, or Fe.

The organic layers may be composed of an organic material having an energy band gap of 2 eV or greater.

The top electrode or the bottom electrode may be composed of Al, Cu, Au, or Pt.

The organic layer may be formed by deposition or coating of a polymer or a monomer.

According to the present invention, a channel exists in a high conductance state or a low conductance state according to an external voltage, and uniformity between devices can be ensured by the use of uniform nano particles, even when highly miniaturized. Accordingly, an organic memory device with excellent characteristics can be provided.

### BRIEF DESCRIPTION OF THE DRAWINGS

The above and other features and advantages of the present invention will become more apparent by describing in detail exemplary embodiments thereof with reference to the attached drawings in which:

FIG. 1A illustrates a sectional view of an organic memory device according to an embodiment of the present invention;

FIG. 1B illustrates a sectional view of an organic memory device according to another embodiment of the present invention; and

FIG. 2 is a graph of current with respect to voltage, illustrating the operation of an organic memory device according to an embodiment of the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

According to an embodiment of the present invention, an organic memory device has electrical bistability. A conventional organic memory device has a metal electrode/organic material/metal layer/organic material/metal electrode structure, and of these layers, the organic material/metal layer/organic material structure forms an electron channel layer. On the other hand, organic memory devices according to the present invention are characterized by the use of nano particles of a certain size instead of the metal layer.

In the embodiments of the present invention, an electron structure of the electron channel layer is substantially changed by a voltage applied to top and bottom electrodes, and thus an electrical conductivity is changed, which is used as memory characteristics. The organic memory device utilizing nano particles and organic/polymer, and a method of manufacturing the same are disclosed. The method includes dispersing nano particles and coating a composite of an organic material and nano particles.

Accordingly, an organic device that can be highly integrated can be formed using a simple manufacturing process, and thereby has better threshold voltage characteristics than a conventional organic memory device. In particular, according to embodiments of the present invention, the conventional thin metal layer is replaced with separately manufactured nano particles of a size within a predetermined range, in order to store electric charge. Therefore, non-uniformity between devices due to the miniaturization can be prevented.

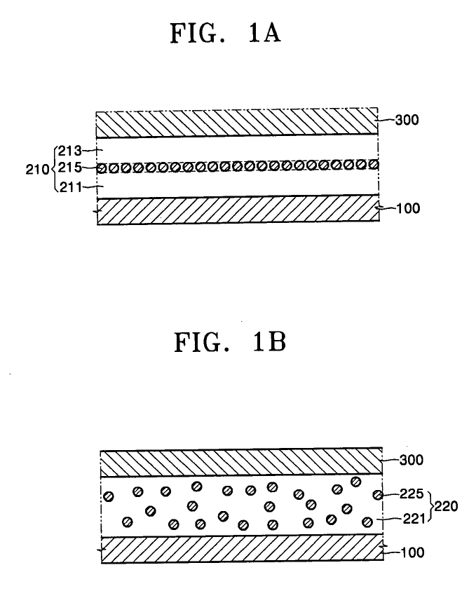

FIG. 1A is a sectional view of an organic memory device according to an embodiment of the present invention, and FIG. 1B is a sectional view of an organic memory device according to another embodiment of the present invention.

Referring to FIG. 1A, the organic memory device according to an embodiment of the present invention includes a bottom electrode 100, an electron channel layer 210, and a top electrode 300. The electron channel layer 210 is a multi-layer composed of a first organic layer 211, a nano particle layer 215, and a second organic layer 213.

The nano particle layer 215 is an array of nano particles, such as Al, Au, Ag, Co, Ni, Fe, an alloy or composite of these, or other similar materials. The nano particles of the nano particle layer 215 are manufactured by chemical synthesis to a uniform size sufficient to store electric charge at room temperature, which may be 1 nm to 20 nm.

The nano particle layer 215 may be formed by dispersing the chemically synthesized nano particles in a solvent to form a nano particle dispersed or suspended solution, coating the nano particle diffusion solution on the coated first organic layer 211, and then vaporizing the solvent. In addition, in order to obtain a uniform two-dimensional array of nano particles, a surfactant can be incorporated in the solution. The surfactant may be mercapto-oleic acid, or a similar substance.

At this time, the nano particles of the nano particle layer 215 are separated by a predetermined distance in the solvent. When the solvent is vaporized, the separated nano particles remain intact on the first organic layer 211. The residual nano particles are fixed by deposition or coating of the second organic layer 213 thereon. That is, the uniform distance between the nano particles of the nano particle layer 215, established when the particle particles were dispersed in the solvent, can be maintained constant.

The first organic layer 211 and/or the second organic layer 213 may be formed by deposition or coating of an organic material with dielectric characteristics, such as a polymer or a monomer. For example, the organic layer 211 and/or the second organic layer 213 may be composed of an organic material with an energy band gap of about 2 eV or greater, thus having semiconducting or insulating characteristics.

The bottom electrode 100 and the top electrode 300 may be composed of Al, Cu, Au or Pt, or an alloy or composite thereof.

Referring to FIG. 1B, an organic memory device according to another embodiment of the present invention includes a bottom electrode 100, an electron channel layer 220, and a top electrode 300. The electron channel layer 220 includes an organic layer 221 and nano particles 225. In detail, the electron channel layer 220 is formed by dispersing nano particles 225 of a uniform size into the organic layer 221.

For example, the synthesized nano particles are mixed with the polymer material such that the metal nano particles can be uniformly distributed in the polymer medium. In order to separate nano particles by a uniform distance, a surfactant can be used to make functional groups on the nano particles. The surfactant may be mercapto-oleic acid, or a similar substance. The nano particles are synthesized separately so that they can have a uniform size of, for example, 1 nm to 20 nm.

The mixture of the nano particles and the polymer is coated onto the bottom electrode 100, thus forming the electron channel layer 220. The organic layer 221 of the electron channel layer 220, as described with reference to FIG. 1A, may be composed of an organic material with dielectric characteristics. For example, the organic layer 221 may be composed of an organic material with an energy band gap of about 2 eV or greater, thus having semiconducting or insulating characteristics.

Meanwhile, in the embodiments of the present invention illustrated in FIGS. 1A and 1B, an improved contact between the organic layer 211, 213, or 221 and the electrode 100 or 300 may be required to attain precise operation of the device. In order to improve the interface characteristics, a glue layer (not shown) may be formed at the interface between the organic layer 211, 213, or 221 and the electrode 100 or 300. Alternatively, a single molecular layer can be attached to the surface of the bottom electrode 100 and/or the organic layer 213 or 211.

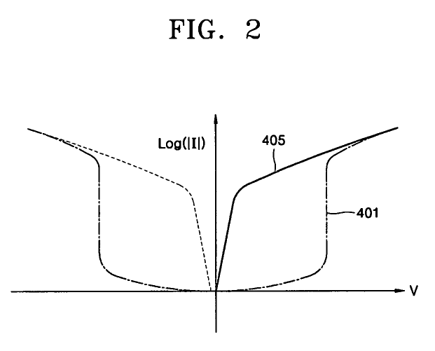

The organic memory devices according to embodiments of the present invention illustrated in FIGS. 1A and 1B exhibit memory effects, because when a voltage is applied to the top and bottom electrodes 100 and 300, the current which flows reflects the conductance state of the structure. The operational characteristics of the organic memory devices are illustrated in FIG. 2.

FIG. 2 is a graph of current with respect to voltage, illustrating the operation of an organic memory device according to an embodiment of the present invention.

Referring to FIG. 2, when a voltage is applied to the top and bottom electrodes 100 and 300 of FIGS. 1A and 1B, a current may flow in a predetermined direction. In addition, the organic devices according to embodiments of the present invention can have a low conductance state 401 and a high conductance state 405. These characteristics allow memory effects to be obtained.

When the applied voltage increases to a threshold voltage Vₜ, the low conductance state 401 exists. However, when the voltage exceeds Vₜ, the low conductance state 401 is converted to the high conductance state 405 by a sudden phase change. When a positive voltage exceeding Vₜ is applied, electrons are injected into the metal nano particles 215 of FIG. 1A or 225 of FIG. 1B through an organic barrier, such as a dielectric. Then, the electron channel layer 210 or 220 is changed to the high conductance state 405 by the injected electrons. In order to change the high conductance state 405 to the low conductance state 401, the polarity of the applied voltage must be changed. That is, when a negative voltage exceeding −Vₜ is applied, the high conductance state 405 is converted to the low conductance state 401.

These operations can be repeated, and each conductance state can be maintained constant over time, allowing organic memory devices according to embodiments of the present invention to be used for non-volatile memory.

In order to attain the sudden reversible phase change between the high conductance state 405 and the low conductance state 401, the organic layer 211 or 213 of FIG. 1A or 221 of FIG. 1B must have semiconducting or insulating characteristics. For example, the energy band gap of the organic layer may be 2 eV or greater, and the nano particles may have a size of 1 nm to 20 nm, which is sufficient to store electric charge.

In organic memory devices according to embodiments of the present invention, a channel exists in a high or low conductance state according to an external voltage. In addition, the use of uniform nano particles can ensure uniformity between devices even when highly miniaturized.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic memory device comprising:
a bottom electrode;
a top electrode facing the bottom electrode; and
an electron channel layer, interposed between the bottom electrode and the top electrode, and comprising:
a first organic layer;
a layer of nano particles separated by a uniform distance and arrayed, on the first organic layer; and
a second organic layer covering the nano particles.

2. The organic memory device of claim 1, wherein the electron channel layer exits in a high conductance state or in a low conductance state according to an external voltage.

3. The organic memory device of claim 1, wherein the size of the nano particle is in the range of 1 nm to 20 nm.

4. The organic memory device of claim 1, wherein the nano particles have a uniform size and are separated from each other by a uniform distance.

5. The organic memory device of claim 1, wherein the nano particles comprise Al, Au, Ag, Co, Ni, or Fe.

6. The organic memory device of claim 1, wherein each of the first and second organic layers is composed of an organic material having an energy band gap of 2 eV or greater.

7. The organic memory device of claim 1, wherein the top electrode or the bottom electrode is composed of Al, Cu, Au, or Pt.

8. An organic memory device comprising:
a bottom electrode;
a top electrode facing the bottom electrode; and
an electron channel layer, interposed between the bottom electrode and the top electrode, and comprising:
an organic layer; and
nano particles which are separated from each other and are dispersed in the organic layer.

9. The organic memory device of claim 8, wherein the electron channel layer exits in a high conductance state or in a low conductance state according to an external voltage.

10. The organic memory device of claim 8, wherein the nano particles have a uniform size and are separated from each other by a uniform distance.

11. The organic memory device of claim 8, wherein the organic layer is composed of an organic material having an energy band gap of 2 eV or greater.

12. A method of manufacturing an organic memory device, the method comprising:
forming a bottom electrode;
forming an electron channel layer comprising an organic layer, in which metal nano particles are dispersed and separated from each other, on the bottom electrode; and
forming a top electrode on the organic layer.

13. The method of claim 12, wherein the forming of the electron channel layer further comprises:
forming a first organic layer on the bottom layer;
dispersing synthesized metal nano particles in a solvent to make a suspension solution;
coating the suspension solution on the first organic layer;
vaporizing the solvent from the coated solution, thus leaving the metal nano particles on the first organic layer; and
forming a second organic layer on the residual metal nano particles.

14. The method of claim 13, wherein the forming of the first organic layer comprises depositing or coating polymers or monomers.

15. The method of claim 13, wherein the forming of the second organic layer comprises depositing or coating polymers or monomers

16. The method of claim 12, wherein the forming of the electron channel layer further comprises:
mixing an organic material and the synthesized metal nano particles; and
coating the resulting mixture on the bottom electrode.
